(19) United States
(12) Patent Application Publication
(10) Pub. No.: US 2015/0089127 A1
(43) Pub. Date: Mar. 26, 2015

(54) MEMORY BROADCAST COMMAND

(71) Applicants: KULJIT S. BAINS, Olympia, WA (US); PETE D. VOGT, Boulder, CO (US)

(72) Inventors: KULJIT S. BAINS, Olympia, WA (US); PETE D. VOGT, Boulder, CO (US)

(21) Appl. No.: 14/033,945

(22) Filed: Sep. 23, 2013

(51) Int. Cl. G11C 7/10

(52) U.S. Cl. CPC G11C 7/1072
USPC 711/106; 711/105

(57) ABSTRACT

Apparatus, systems, and methods to broadcast a memory command are described. In one embodiment, a memory controller comprising logic to insert a first predetermined value into an all ranks parameter in a memory command, and transmit the memory command to a memory device. Other embodiments are also disclosed and claimed.

### FIELD

The present disclosure generally relates to the field of electronics. More particularly, some embodiments of the invention generally relate to memory.

### BACKGROUND

Volatile memory technology such as Dynamic Random Access Memory (DRAM) technologies for example, JEDEC standard DRAM such as Dual Data Rate-3 (DDR3), Dual Data Rate 4 (DDR4), Low Power Dual Data Rate 2 (LPDDR2) and Low Power Dual Data Rated 3 (LPDDR3) use a dedicated chip select pin (CS#) per rank of memory. This enables a memory controller to send a command that is broadcasted to all ranks of memory by asserting all of the CS# pins. Examples of commands that are typically broadcasted by the memory controller to the memory ranks are MRW (mode register write), self refresh entry and precharge all.

### BRIEF DESCRIPTION OF THE DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIG. 1 is a schematic, block diagram illustration of components of an electronic device which may be adapted to implement a memory broadcast command in accordance with various embodiments discussed herein.

FIG. 2 is a schematic, block diagram illustration of components of apparatus to implement a memory broadcast command in accordance with various embodiments discussed herein.

FIG. 3 is a schematic illustration of a memory in accordance with various embodiments discussed herein.

FIG. 4 is a flowchart illustrating operations in a method to implement a memory broadcast command in accordance with various embodiments discussed herein.

FIG. 5 is a table illustrating various memory commands in accordance with various embodiments discussed herein.

FIGS. 6-10 are schematic, block diagram illustrations of electronic devices which may be adapted to implement a memory broadcast command in accordance with various embodiments discussed herein.

### DETAILED DESCRIPTION

In the following description, numerous specific details are set forth in order to provide a thorough understanding of various embodiments. However, various embodiments of the invention may be practiced without the specific details. In other instances, well-known methods, procedures, components, and circuits have not been described in detail so as not to obscure the particular embodiments of the invention. Further, various aspects of embodiments of the invention may be performed using various means, such as integrated semiconductor circuits (“hardware”), computer-readable instructions organized into one or more programs (“software”), or some combination of hardware and software. For the purposes of this disclosure reference to “logic” shall mean either hardware, software, or some combination thereof.

Memory technologies such as Wide Input/Output 2 (WIO2) and LPDDR4 may eliminate CS# pins in order to reduce pin count in the memory controller. A single rank select pin (RS) in the memory controller may be used to broadcast commands to designated memory ranks. In a two rank memory system if the RS pin=0 then the command is for the first rank and if RS=1 then the command is for the second rank.

However, eliminating the multiple chip select (CS#) pins in the memory controller effectively eliminates the ability to broadcast commands to all ranks in a memory system. Accordingly, encoding techniques which can broadcast commands to all ranks may find utility, e.g., in memory systems.

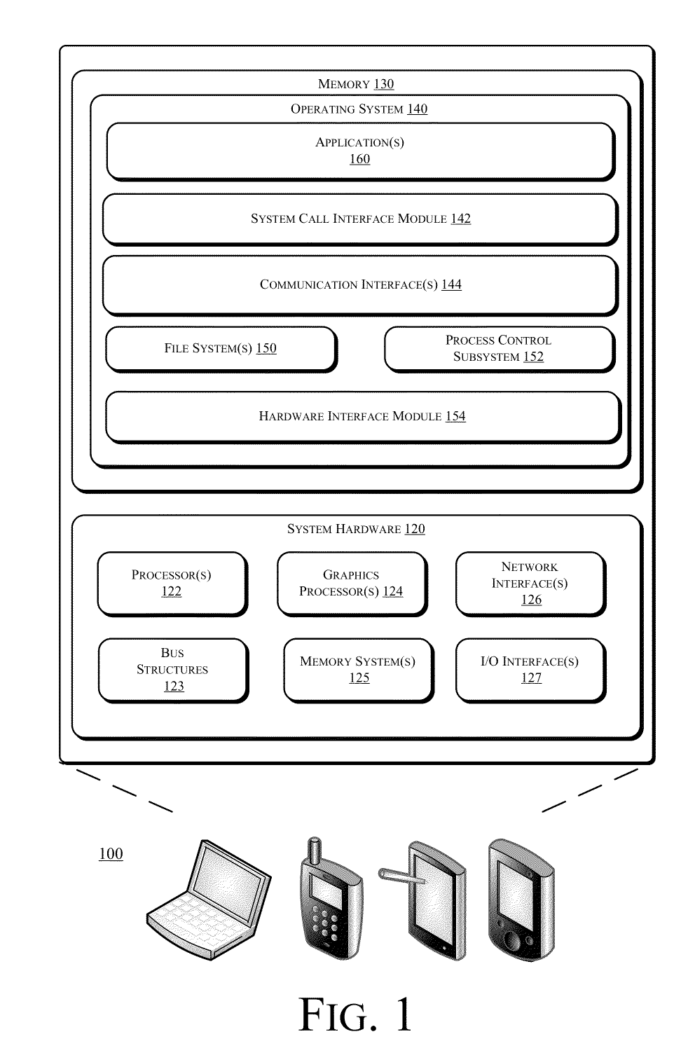

FIG. 1 is a schematic illustration of an exemplary electronic device 100 which may be adapted incorporate a memory broadcast command as described herein, in accordance with some embodiments. In various embodiments, the electronic device 100 may be embodied as a personal computer, a laptop computer, a personal digital assistant, a mobile telephone, an entertainment device, a tablet computer, an electronic reader, or another computing device.

The electronic device 100 includes system hardware 120 and memory 130, which may be implemented as random access memory and/or read-only memory. System hardware 120 may include one or more processors 122, bus structures 123, one or more graphics processors 124, memory systems 125, network interfaces 126, and input/output interfaces 127. In one embodiment, processor 122 may be embodied as an Intel® Core2 Duo® processor available from Intel Corporation, Santa Clara, Calif., USA. As used herein, the term “processor” means any type of computational element, such as but not limited to, a microprocessor, a microcontroller, a complex instruction set computing (CISC) microprocessor, a reduced instruction set (RISC) microprocessor, a very long instruction word (VLIW) microprocessor, or any other type of processor or processing circuit.

Bus structures 123 connect various components of system hardware 120. In one embodiment, bus structures 123 may be one or more of several types of bus structure(s) including a memory bus, a peripheral bus or external bus, and/or a local bus using any variety of available bus architectures including, but not limited to, 11-bit bus, Industrial Standard Architecture (ISA), Micro-Channel Architecture (MSA), Extended ISA (EISA), Intelligent Drive Electronics (IDE), VESA Local Bus (VLB), Peripheral Component Interconnect (PCI), Universal Serial Bus (USB), Advanced Graphics Port (AGP), Personal Computer Memory Card International Association bus (PCMCIA), and Small Computer Systems Interface (SCSI).

Graphics processor(s) 124 may function as adjunct processor that manages graphics and/or video operations. Graphics processor(s) 124 may be integrated onto the motherboard of electronic device 100 or may be coupled via an expansion slot on the motherboard.

Memory systems 125 may comprise local memory, e.g., cache memory, one or more forms of volatile memory and nonvolatile memory, as described below.

In one embodiment, network interface(s) 126 could be a wired interface such as an Ethernet interface (see, e.g., Institute of Electrical and Electronics Engineers/IEEE 802.3-2002) or a wireless interface such as an IEEE 802.11a, b or g-compliant interface (see, e.g., IEEE Standard for IT-Telecommunications and information exchange between systems LAN/MAN—Part II: Wireless LAN Medium Access Control (MAC) and Physical Layer (PHY) specifications Amendment 4: Further Higher Data Rate Extension in the 2.4 GHz Band, 802.11G-2003). Another example of a wireless interface would be a general packet radio service (GPRS) interface (see, e.g., Guidelines on GPRS Handset Requirements, Global System for Mobile Communications/GSM Association, Ver. 3.0.1, December 2002).

I/O interface(s) 127 may be implemented on one or more I/O devices, e.g., a display, a touch screen, one or more speakers, a keyboard, a mouse, a touchpad, or the like.

Memory 130 may store an operating system 140 for managing operations of electronic device 100. In one embodiment, operating system 140 includes a hardware interface module 154, e.g., one or more operating system device drivers, that provides an interface to system hardware 120. In addition, operating system 140 may include a file system 150 that manages files used in the operation of electronic device 100 and a process control subsystem 152 that manages processes executing on electronic device 100.

Operating system 140 may include (or manage) one or more communication interfaces 144 that may operate in conjunction with system hardware 120 to transceive data packets and/or data streams from a remote source. Operating system 140 may further include a system call interface module 142 that provides an interface between the operating system 140 and one or more application modules resident in memory 130. Operating system 140 may be embodied as a UNIX operating system or any derivative thereof (e.g., Linux, Solaris, etc.) or as a Windows® brand operating system, or other operating systems.

In some embodiments memory 130 may store one or more applications 160 which may execute on the one or more processors 122 under the supervision of operating system 140. The applications 160 may be embodied as logic instructions stored in a tangible, non-transitory computer readable medium (i.e., software or firmware) which may be executable on one or more of the processors 122. Alternatively, these applications may be embodied as logic on a programmable device such as a field programmable gate array (FPGA) or the like. Alternatively, these applications may be reduced to logic that may be hardwired into an integrated circuit.

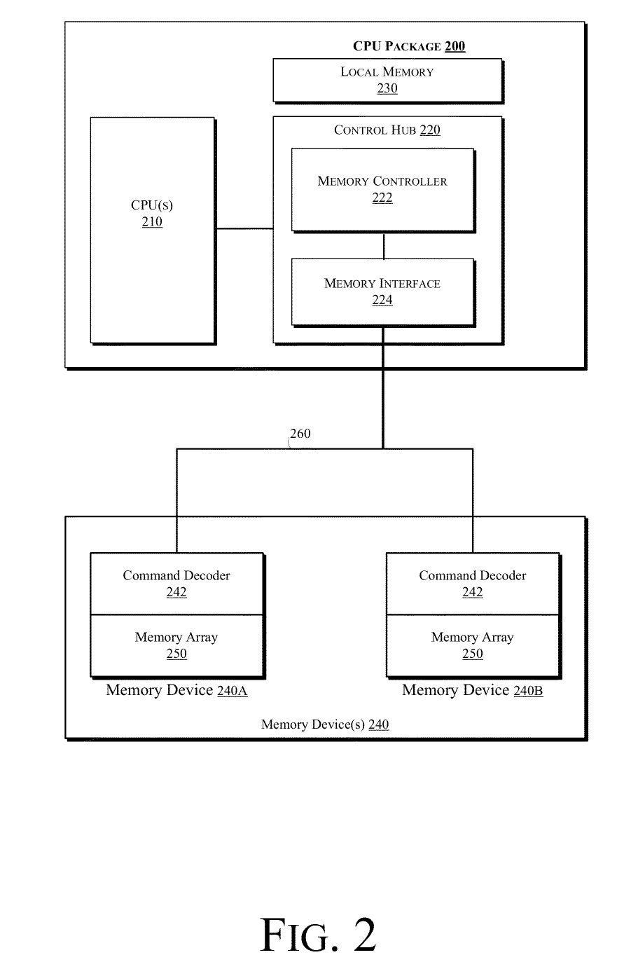

FIG. 2 is a schematic, block diagram illustration of components of apparatus to implement methods to broadcast commands to a plurality of ranks in a memory system. Referring to FIG. 2, in some embodiments a central processing unit (CPU) package 200 which may comprise one or more CPUs 210 coupled to a control hub 220 and a local memory 230. Control hub 220 comprises a memory controller 222 and a memory interface 224.

Memory interface 224 is coupled to one or more remote memory devices 240A, 240B, which may be referred to collectively by reference numeral 240, by a communication bus 260. Memory devices 240 may comprise a command decoder 242 and one or more memory arrays 250. In various embodiments, memory arrays 250 may be implemented using dynamic random access memory (DRAM) memory, e.g., low-power double data rate (LPDDR) DRAM, Wide Input/Output (WIO) DRAM. By way of example, in some embodiments the memory device(s) 240 may comprise one or more direct in-line memory modules (DIMMs) coupled to a memory channel which provides a communication link to command decoder 242. The specific configuration of the memory arrays 250 in the memory devices 240 is not critical.

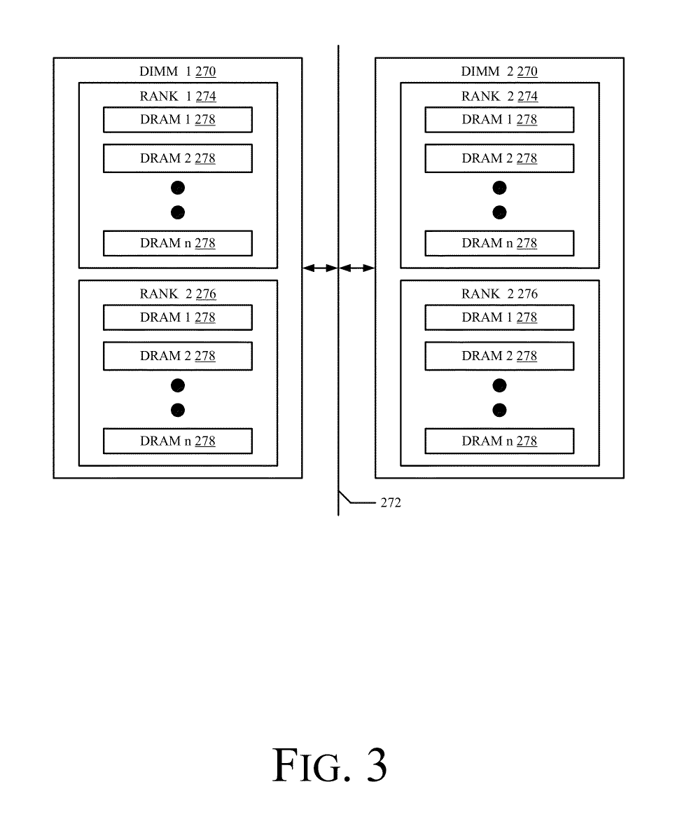

By way of example, referring to FIG. 3, in some embodiments the memory array 250 may comprise one or more direct in-line memory modules (DIMMs) 270 coupled to a memory channel 272 which provides a communication link to memory command decoder 242. In the embodiment depicted in FIG. 3 each DIMM 270 comprises a first rank 274 and a second rank 276, each of which includes a plurality of DRAM modules 278. One skilled in the art will recognize that memory array 250 may comprise more or fewer DIMMs 270, and more or fewer ranks per DIMM. Further, some electronic devices (e.g., smart phones, tablet computers, and the like) may comprise simpler memory systems comprised of one or more DRAMs.

In some embodiments logic in the memory controller 222 and the command decoder 242 cooperate to implement methods to broadcast commands to multiple ranks 274, 276 in DIMMs 240. More particularly, in some embodiments logic in the memory controller 222 implements operations to insert a first predetermined value into an all ranks parameter in a memory command before the memory command is passed to the memory devices 240 and the command decoder 242 implements operations to broadcast the memory command to all ranks in the memory devices 240 when the all ranks parameter includes the predetermined value. In some embodiments the memory broadcast parameter may be implemented by setting an all ranks parameter to either a logic low (i.e., a “0”) if the memory command is not to be broadcast, or to a logic high (i.e., a “1”) if the memory command is to be broadcast.

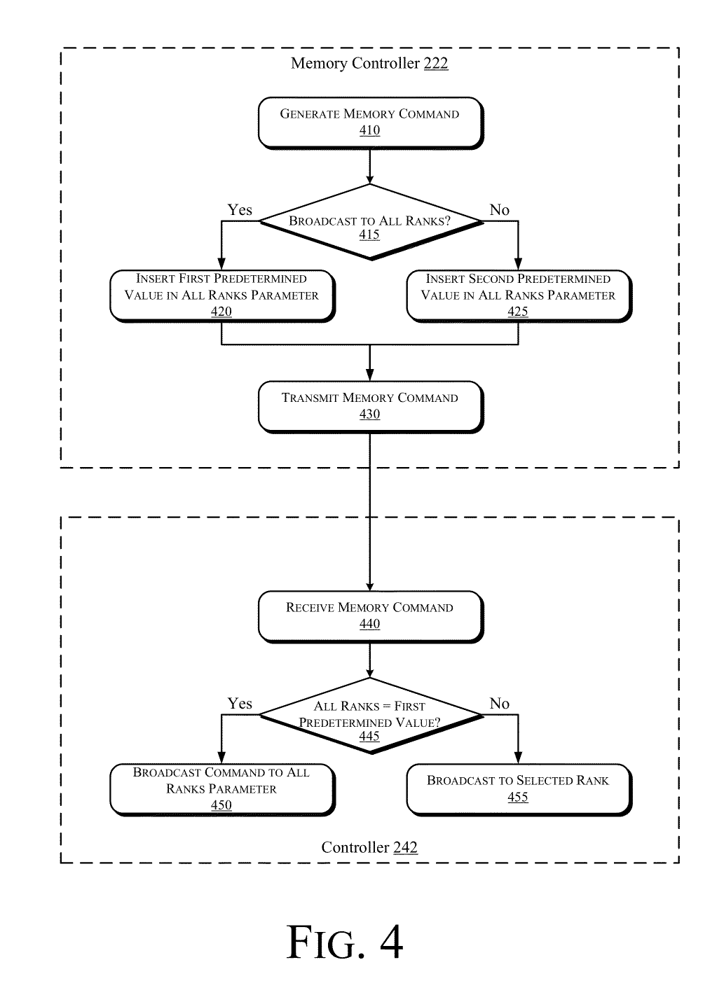

Operations implemented by memory controller 222 and the command decoder 242 will be described with reference to FIG. 4. Referring to FIG. 4, at operation 410 the memory controller 222 generates a memory command for the memory array 250 in memory devices 240. By way of example, in operation memory controller 222 receives a request from a host, e.g., from an application 160 executing on processor(s) 122 to access or write data to memory device(s) 140. Alternatively, memory controller 222 may generate commands in response to other events, e.g., a refresh command in response to a refresh time period elapsing, or other events.

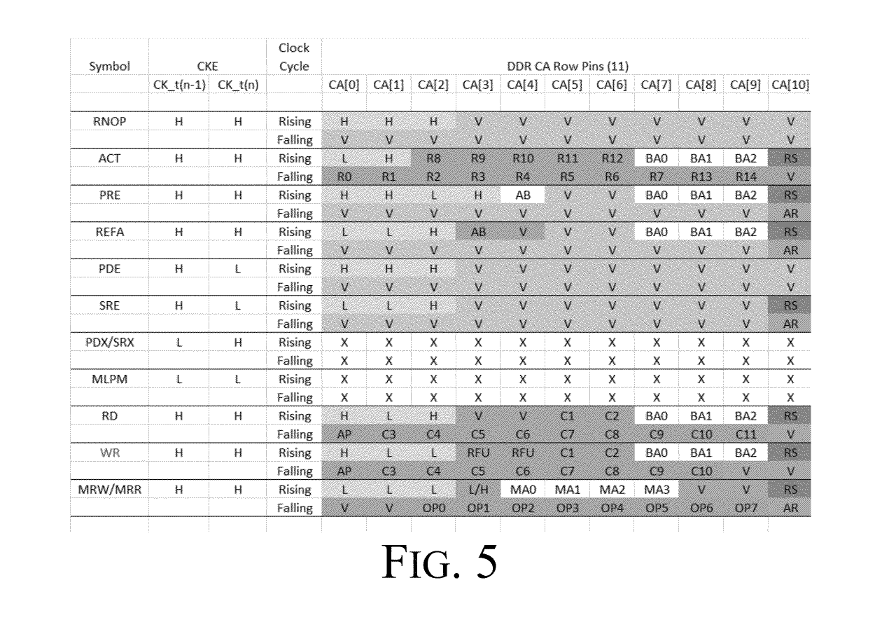

At operation 410 the memory controller 222 determines whether the command is to be broadcast to all ranks 274, 276. In some embodiments the controller 222 may be configured to encode specific memory commands as “all rank” broadcast commands, which may in some cases be broadcast to all ranks 274, 276 in a memory device. FIG. 5 presents one example of command encoding which may be implemented by memory controller 222. In the example depicted in FIG. 5 the memory controller 222 may be configured to designate the precharge (PRE) command, the refresh (REFA) command, the self refresh entry (SRE) command, and the mode register write/mode register read (MRW/MRR) command as all rank broadcast commands. In the example depicted in FIG. 5 each command which is encoded with an all rank parameter also is encoded with a “rank select” parameter which identifies one or more ranks to which the memory command is to be broadcast.

If, at operation 415, the message it so be broadcast to all ranks, then control passes to operation 420 and the memory controller 222 inserts a first predetermined value into an all ranks parameter in the memory command. As described above, in some embodiments the memory controller 222 inserts a binary “1” into an all ranks bit in the memory command. By contrast, the message is not to be broadcast to all ranks then control passes to operation 425 and the memory controller 222 inserts a second predetermined value into an all ranks parameter in the memory command. As described above, in some embodiments the memory controller 222 inserts a binary “0” into an all ranks bit in the memory command.

At operation 430 the memory command is transmitted from the memory controller 222 to the memory devices 240. By way of example, memory controller 222 may place the command on communication bus 260 via the memory interface 224.

At operation 440 the command decoder 242 receives the memory command, and at operation 445 the command decoder 242 determines whether the command is to be broadcast to all ranks by examining the all ranks parameter. If, at operation 445, the all ranks parameter is set to the first predetermined value (e.g., a logic “1”) then control passes to operation 450 and the memory command is broadcast to all ranks in the memory devices 240. Stated otherwise, if the all ranks parameter is set to the first predetermined value then the controller disregards the rank select parameter and broadcasts the command to all ranks. By contrast, if at operation 445, the all ranks parameter is set to the second predetermined value (e.g., a logic “0”) then control passes to operation 455 and the memory command is broadcasted to the rank(s) associated with the rank select parameter in the memory device(s) 240.

Thus, described herein is a command encoding scheme which enables a memory system in an electronic device to implement command broadcast to all ranks of memory chips in the memory system.

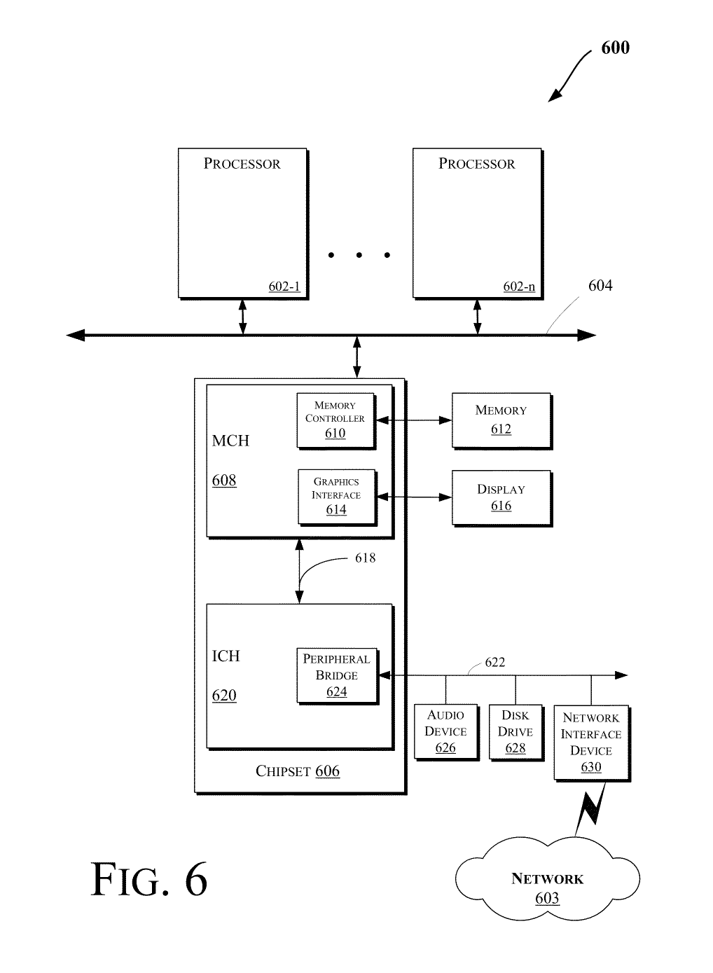

As described above, in some embodiments the electronic device may be embodied as a computer system. FIG. 6 illustrates a block diagram of a computing system 600 in accordance with an embodiment of the invention. The computing system 600 may include one or more central processing unit(s) (CPUs) 602 or processors that communicate via an interconnection network (or bus) 604. The processors 602 may include a general purpose processor, a network processor (that processes data communicated over a computer network 603), or other types of a processor (including a reduced instruction set computer (RISC) processor or a complex instruction set computer (CISC)). Moreover, the processors 602 may have a single or multiple core design. The processors 602 with a multiple core design may integrate different types of processor cores on the same integrated circuit (IC) die. Also, the processors 602 with a multiple core design may be implemented as symmetrical or asymmetrical multiprocessors. In an embodiment, one or more of the processors 602 may be the same or similar to the processors 102 of FIG. 1. For example, one or more of the processors 602 may include the control unit 120 discussed with reference to FIGS. 1-3. Also, the operations discussed with reference to FIGS. 3-5 may be performed by one or more components of the system 600.

A chipset 606 may also communicate with the interconnection network 604. The chipset 606 may include a memory control hub (MCH) 608. The MCH 608 may include a memory controller 610 that communicates with a memory 612 (which may be the same or similar to the memory 130 of FIG. 1). The memory 412 may store data, including sequences of instructions, that may be executed by the CPU 602, or any other device included in the computing system 600. In one embodiment of the invention, the memory 612 may include one or more volatile storage (or memory) devices such as random access memory (RAM), dynamic RAM (DRAM), synchronous DRAM (SDRAM), static RAM (SRAM), or other types of storage devices. Nonvolatile memory may also be utilized such as a hard disk. Additional devices may communicate via the interconnection network 604, such as multiple CPUs and/or multiple system memories.

The MCH 608 may also include a graphics interface 614 that communicates with a display device 616. In one embodiment of the invention, the graphics interface 614 may communicate with the display device 616 via an accelerated graphics port (AGP). In an embodiment of the invention, the display 616 (such as a flat panel display) may communicate with the graphics interface 614 through, for example, a signal converter that translates a digital representation of an image stored in a storage device such as video memory or system memory into display signals that are interpreted and displayed by the display 616. The display signals produced by the display device may pass through various control devices before being interpreted by and subsequently displayed on the display 616.

A hub interface 618 may allow the MCH 608 and an input/output control hub (ICH) 620 to communicate. The ICH 620 may provide an interface to I/O device(s) that communicate with the computing system 600. The ICH 620 may communicate with a bus 622 through a peripheral bridge (or controller) 624, such as a peripheral component interconnect (PCI) bridge, a universal serial bus (USB) controller, or other types of peripheral bridges or controllers. The bridge 624 may provide a data path between the CPU 602 and peripheral devices. Other types of topologies may be utilized. Also, multiple buses may communicate with the ICH 620, e.g., through multiple bridges or controllers. Moreover, other peripherals in communication with the ICH 620 may include, in various embodiments of the invention, integrated drive electronics (IDE) or small computer system interface (SCSI) hard drive(s), USB port(s), a keyboard, a mouse, parallel port(s), serial port(s), floppy disk drive(s), digital output support (e.g., digital video interface (DVI)), or other devices.

The bus 622 may communicate with an audio device 626, one or more disk drive(s) 628, and a network interface device 630 (which is in communication with the computer network 603). Other devices may communicate via the bus 622. Also, various components (such as the network interface device 630) may communicate with the MCH 608 in some embodiments of the invention. In addition, the processor 602 and one or more other components discussed herein may be combined to form a single chip (e.g., to provide a System on Chip (SOC)). Furthermore, the graphics accelerator 616 may be included within the MCH 608 in other embodiments of the invention.

Furthermore, the computing system 600 may include volatile and/or nonvolatile memory (or storage). For example, nonvolatile memory may include one or more of the following: read-only memory (ROM), programmable ROM (PROM), erasable PROM (EPROM), electrically EPROM (EEPROM), a disk drive (e.g., 628), a floppy disk, a compact disk ROM (CD-ROM), a digital versatile disk (DVD), flash memory, a magneto-optical disk, or other types of nonvolatile machine-readable media that are capable of storing electronic data (e.g., including instructions).

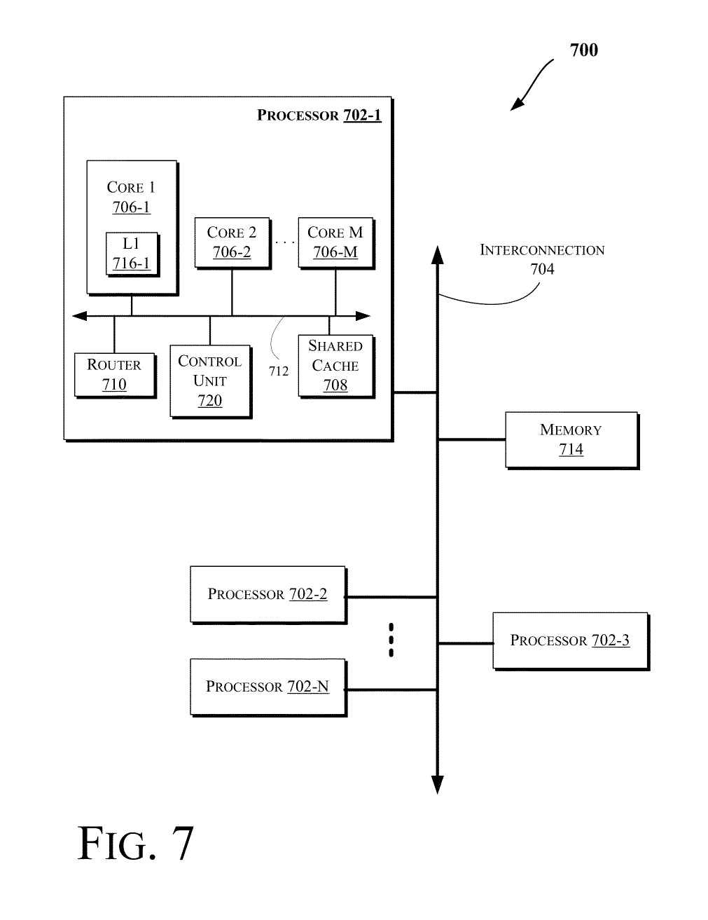

FIG. 7 illustrates a block diagram of a computing system 700, according to an embodiment of the invention. The system 700 may include one or more processors 702-1 through 702-N (generally referred to herein as “processors 702” or “processor 702”). The processors 702 may communicate via an interconnection network or bus 704. Each processor may include various components some of which are only discussed with reference to processor 702-1 for clarity. Accordingly, each of the remaining processors 702-2 through 702-N may include the same or similar components discussed with reference to the processor 702-1.

In an embodiment, the processor 702-1 may include one or more processor cores 706-1 through 706-M (referred to herein as “cores 706” or more generally as “core 706”), a shared cache 708, a router 710, and/or a processor control logic or unit 720. The processor cores 706 may be implemented on a single integrated circuit (IC) chip. Moreover, the chip may include one or more shared and/or private caches (such as cache 708), buses or interconnections (such as a bus or interconnection network 712), memory controllers, or other components.

In one embodiment, the router 710 may be used to communicate between various components of the processor 702-1 and/or system 700. Moreover, the processor 702-1 may include more than one router 710. Furthermore, the multitude of routers 710 may be in communication to enable data routing between various components inside or outside of the processor 702-1.

The shared cache 708 may store data (e.g., including instructions) that are utilized by one or more components of the processor 702-1, such as the cores 706. For example, the shared cache 708 may locally cache data stored in a memory 714 for faster access by components of the processor 702. In an embodiment, the cache 708 may include a mid-level cache (such as a level 2 (L2), a level 3 (L3), a level 4 (L4), or other levels of cache), a last level cache (LLC), and/or combinations thereof. Moreover, various components of the processor 702-1 may communicate with the shared cache 708 directly, through a bus (e.g., the bus 712), and/or a memory controller or hub. As shown in FIG. 7, in some embodiments, one or more of the cores 706 may include a level 1 (L1) cache 716-1 (generally referred to herein as “L1 cache 716”). In one embodiment, the control unit 720 may include logic to implement the operations described above with reference to the memory controller 122 in FIG. 2.

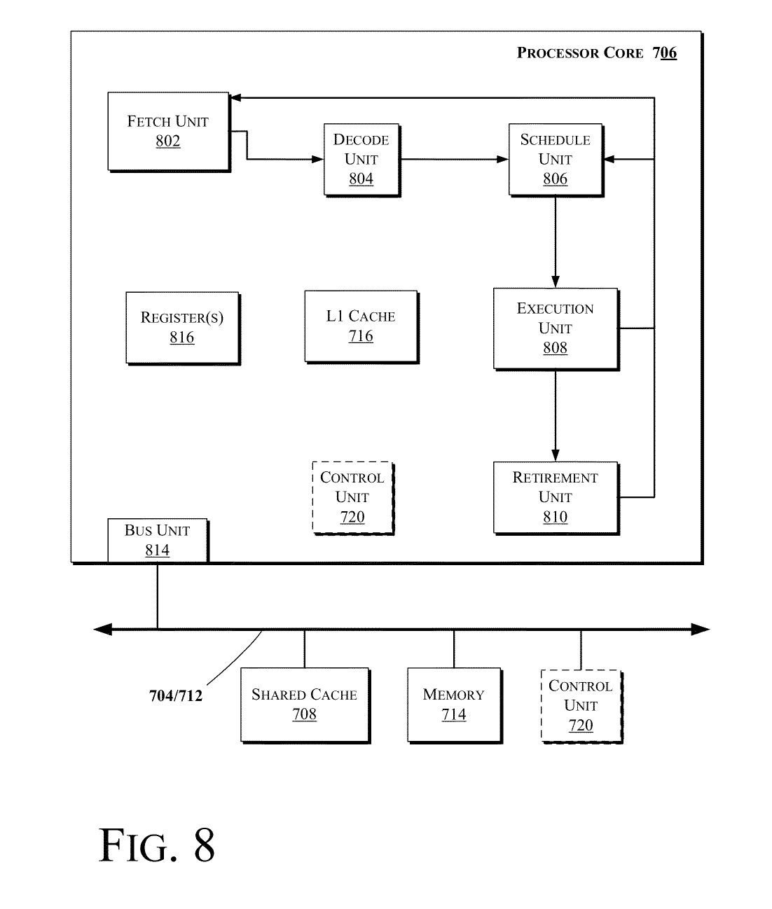

FIG. 8 illustrates a block diagram of portions of a processor core 706 and other components of a computing system, according to an embodiment of the invention. In one embodiment, the arrows shown in FIG. 8 illustrate the flow direction of instructions through the core 706. One or more processor cores (such as the processor core 706) may be implemented on a single integrated circuit chip (or die) such as discussed with reference to FIG. 7. Moreover, the chip may include one or more shared and/or private caches (e.g., cache 708 of FIG. 7), interconnections (e.g., interconnections 704 and/or 112 of FIG. 7), control units, memory controllers, or other components.

As illustrated in FIG. 8, the processor core 706 may include a fetch unit 802 to fetch instructions (including instructions with conditional branches) for execution by the core 706. The instructions may be fetched from any storage devices such as the memory 714. The core 706 may also include a decode unit 804 to decode the fetched instruction. For instance, the decode unit 804 may decode the fetched instruction into a plurality of uops (micro-operations).

Additionally, the core 706 may include a schedule unit 806. The schedule unit 806 may perform various operations associated with storing decoded instructions (e.g., received from the decode unit 804) until the instructions are ready for dispatch, e.g., until all source values of a decoded instruction become available. In one embodiment, the schedule unit 806 may schedule and/or issue (or dispatch) decoded instructions to an execution unit 808 for execution. The execution unit 808 may execute the dispatched instructions after they are decoded (e.g., by the decode unit 804) and dispatched (e.g., by the schedule unit 806). In an embodiment, the execution unit 808 may include more than one execution unit. The execution unit 808 may also perform various arithmetic operations such as addition, subtraction, multiplication, and/or division, and may include one or more an arithmetic logic units (ALUs). In an embodiment, a co-processor (not shown) may perform various arithmetic operations in conjunction with the execution unit 808.

Further, the execution unit 808 may execute instructions out-of-order. Hence, the processor core 706 may be an out-of-order processor core in one embodiment. The core 706 may also include a retirement unit 810. The retirement unit 810 may retire executed instructions after they are committed. In an embodiment, retirement of the executed instructions may result in processor state being committed from the execution of the instructions, physical registers used by the instructions being de-allocated, etc.

The core 706 may also include a bus unit 714 to enable communication between components of the processor core 706 and other components (such as the components discussed with reference to FIG. 8) via one or more buses (e.g., buses 804 and/or 812). The core 706 may also include one or more registers 816 to store data accessed by various components of the core 706 (such as values related to power consumption state settings).

Furthermore, even though FIG. 7 illustrates the control unit 720 to be coupled to the core 706 via interconnect 812, in various embodiments the control unit 720 may be located elsewhere such as inside the core 706, coupled to the core via bus 704, etc.

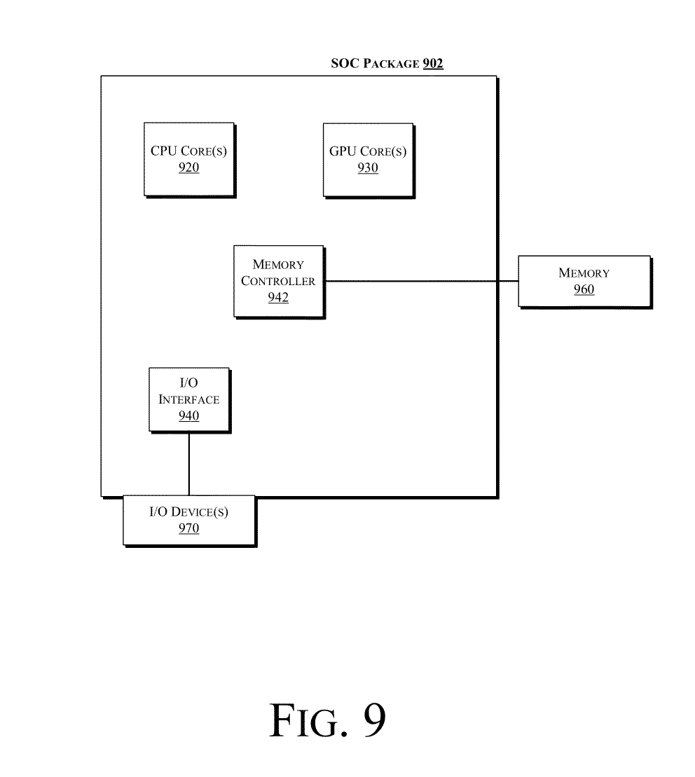

In some embodiments, one or more of the components discussed herein can be embodied as a System On Chip (SOC) device. FIG. 9 illustrates a block diagram of an SOC package in accordance with an embodiment. As illustrated in FIG. 9, SOC 902 includes one or more Central Processing Unit (CPU) cores 920, one or more Graphics Processor Unit (GPU) cores 930, an Input/Output (I/O) interface 940, and a memory controller 942. Various components of the SOC package 902 may be coupled to an interconnect or bus such as discussed herein with reference to the other figures. Also, the SOC package 902 may include more or less components, such as those discussed herein with reference to the other figures. Further, each component of the SOC package 902 may include one or more other components, e.g., as discussed with reference to the other figures herein. In one embodiment, SOC package 902 (and its components) is provided on one or more Integrated Circuit (IC) die, e.g., which are packaged into a single semiconductor device.

As illustrated in FIG. 9, SOC package 902 is coupled to a memory 960 (which may be similar to or the same as memory discussed herein with reference to the other figures) via the memory controller 942. In an embodiment, the memory 960 (or a portion of it) can be integrated on the SOC package 902.

The I/O interface 940 may be coupled to one or more I/O devices 970, e.g., via an interconnect and/or bus such as discussed herein with reference to other figures. I/O device(s) 970 may include one or more of a keyboard, a mouse, a touchpad, a display, an image/video capture device (such as a camera or camcorder/video recorder), a touch screen, a speaker, or the like.

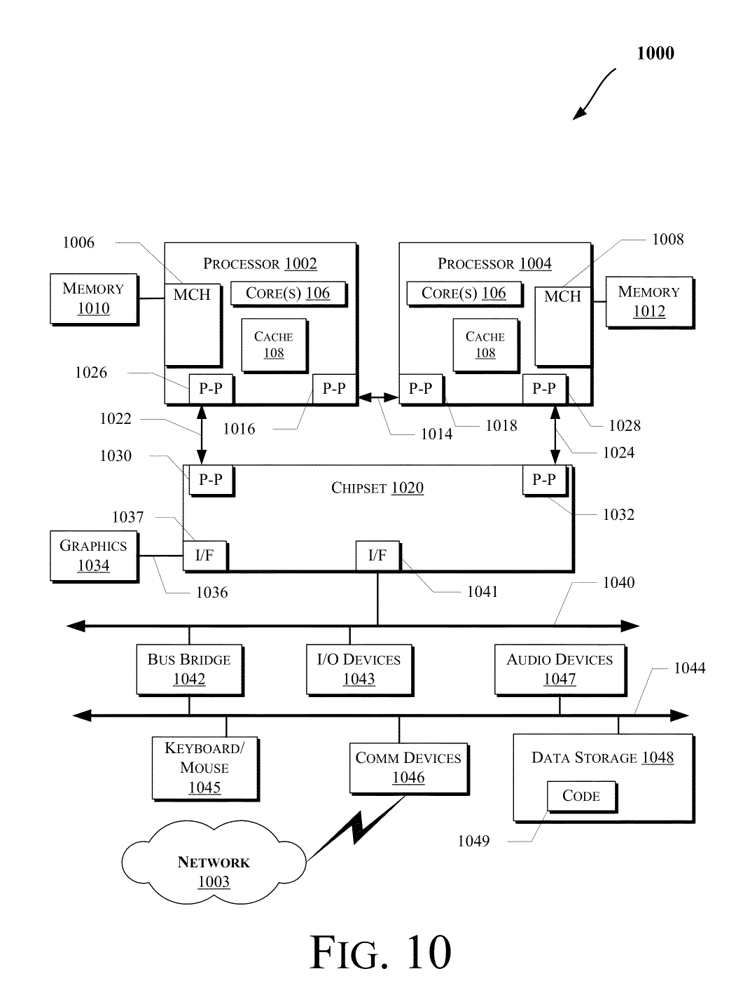

FIG. 10 illustrates a computing system 1000 that is arranged in a point-to-point (PtP) configuration, according to an embodiment of the invention. In particular, FIG. 10 shows a system where processors, memory, and input/output devices are interconnected by a number of point-to-point interfaces. The operations discussed with reference to FIG. 2 may be performed by one or more components of the system 1000.

As illustrated in FIG. 10, the system 1000 may include several processors, of which only two, processors 1002 and 1004 are shown for clarity. The processors 1002 and 1004 may each include a local memory controller hub (MCH) 1006 and 1008 to enable communication with memories 1010 and 1012. MCH 1006 and 1008 may include the memory controller 120 and/or logic of FIG. 1 in some embodiments.

In an embodiment, the processors 1002 and 1004 may be one of the processors 702 discussed with reference to FIG. 7. The processors 1002 and 1004 may exchange data via a point-to-point (PtP) interface 1014 using PtP interface circuits 1016 and 1018, respectively. Also, the processors 1002 and 1004 may each exchange data with a chipset 1020 via individual PtP interfaces 1022 and 1024 using point-to-point interface circuits 1026, 1028, 1030, and 1032. The chipset 1020 may further exchange data with a high-performance graphics circuit 1034 via a high-performance graphics interface 1036, e.g., using a PtP interface circuit 1037.

As shown in FIG. 10, one or more of the cores 106 and/or cache 108 of FIG. 1 may be located within the processors 1002 and 1004. Other embodiments of the invention, however, may exist in other circuits, logic units, or devices within the system 1000 of FIG. 10. Furthermore, other embodiments of the invention may be distributed throughout several circuits, logic units, or devices illustrated in FIG. 10.

The chipset 1020 may communicate with a bus 1040 using a PtP interface circuit 1041. The bus 1040 may have one or more devices that communicate with it, such as a bus bridge 1042 and I/O devices 1043. Via a bus 1044, the bus bridge 1043 may communicate with other devices such as a keyboard/mouse 1045, communication devices 1046 (such as modems, network interface devices, or other communication devices that may communicate with the computer network 803), audio I/O device, and/or a data storage device 1048. The data storage device 1048 (which may be a hard disk drive or a NAND flash based solid state drive) may store code 1049 that may be executed by the processors 1002 and/or 1004.

The following examples pertain to further embodiments.

Example 1 is memory controller comprising logic to insert a first predetermined value into an all ranks parameter in a memory command and transmit the memory command to a memory device.

In Example 2, the subject matter of Example 1 can optionally include logic to determine whether a memory command is to be broadcast to all ranks in a memory device, and in response to a determination that the memory command is to be broadcast to all ranks in a memory device, insert the first predetermined value into the all ranks parameter.

In Example 3, the subject matter of any one of Examples 1-2 can optionally include a memory command which comprises at least one of an activate command, a precharge command, or a refresh command.

In Example 4, the subject matter of any one of Examples 1-3 can optionally include an arrangement in which the command is transmitted to the memory device via a memory interface.

Example 5 is an apparatus comprising a processor and a memory control logic to insert a first predetermined value into an all ranks parameter in a memory command and transmit the memory command to a memory device.

In Example 6, the subject matter of Example 5 can optionally include logic to determine whether a memory command is to be broadcast to all ranks in a memory device, and in response to a determination that the memory command is to be broadcast to all ranks in a memory device, insert the first predetermined value into the all ranks parameter.

In Example 7, the subject matter of any one of Examples 5-6 can optionally include a memory command which comprises at least one of an activate command, a precharge command, or a refresh command.

In Example 8, the subject matter of any one of Examples 5-7 can optionally include an arrangement in which the command is transmitted to the memory device via a memory interface.

Example 9 is a command decoder comprising logic to receive a memory command comprising an all ranks parameter and broadcast the memory command to all ranks in a memory device coupled to the command decoder when the all ranks parameter holds a first predetermined value.

In Example 10, the subject matter of Example 9 can optionally include logic to disregard the rank select parameter when the all ranks parameter holds the first predetermined value.

In Example 11, the subject matter of any one of Examples 9-10 can optionally include logic to apply the rank select parameter when the all ranks parameter holds a second predetermined value.

Example 12 is a memory device, comprising a plurality of memory chips organized into two or more memory ranks, a command decoder coupled to the plurality of memory chips comprising logic to receive a memory command comprising an all ranks parameter, and broadcast the memory command to all ranks in a memory device coupled to the command decoder when the all ranks parameter holds a first predetermined value.

In Example 13, the subject matter of Example 12 can optionally include logic to disregard the rank select parameter when the all ranks parameter holds the first predetermined value.

In Example 14, the subject matter of any one of Examples 12-13 can optionally include logic to apply the rank select parameter when the all ranks parameter holds a second predetermined value.

Example 15 is an electronic device, comprising at least one electronic component, a memory controller comprising logic to insert a predetermined value into an all ranks parameter in a memory command and transmit the memory command to a memory device, the memory device comprising a plurality of memory chips organized into two or more memory ranks a command decoder coupled to the plurality of memory chips comprising logic to receive the memory command comprising the all ranks parameter and broadcast the memory command to all ranks in the memory device coupled to the command decoder when the all ranks parameter holds a first predetermined value.

In Example 16, the subject matter of Example 15 can optionally include logic to determine whether a memory command is to be broadcast to all ranks in a memory device, and in response to a determination that the memory command is to be broadcast to all ranks in a memory device, insert the first predetermined value into the all ranks parameter.

In Example 17, the subject matter of any one of Examples 15-16 can optionally include a memory command which comprises at least one of an activate command, a precharge command, or a refresh command.

In Example 18, the subject matter of any one of Examples 15-17 can optionally include an arrangement in which the command is transmitted to the memory device via a memory interface.

In Example 19, the subject matter of any one of Examples 15-18 can optionally include an arrangement in which the memory command further comprises a rank select parameter, and the command decoder further comprises logic to disregard the rank select parameter when the all ranks parameter holds the first predetermined value.

In Example 20, the subject matter of any one of Examples 15-19 can optionally include logic to apply the rank select parameter when the all ranks parameter holds a second predetermined value.

In various embodiments of the invention, the operations discussed herein, e.g., with reference to FIGS. 1-10, may be implemented as hardware (e.g., circuitry), software, firmware, microcode, or combinations thereof, which may be provided as a computer program product, e.g., including a tangible (e.g., non-transitory) machine-readable or computer-readable medium having stored thereon instructions (or software procedures) used to program a computer to perform a process discussed herein. Also, the term “logic” may include, by way of example, software, hardware, or combinations of software and hardware. The machine-readable medium may include a storage device such as those discussed herein.

Reference in the specification to “one embodiment” or “an embodiment” means that a particular feature, structure, or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments of the invention, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

Thus, although embodiments of the invention have been described in language specific to structural features and/or methodological acts, it is to be understood that claimed subject matter may not be limited to the specific features or acts described. Rather, the specific features and acts are disclosed as sample forms of implementing the claimed subject matter.

1. A memory controller comprising logic to:
insert a first predetermined value into an all ranks parameter in a memory command; and
transmit the memory command to a memory device.

2. The memory controller of claim 1, further comprising logic to:
determine whether a memory command is to be broadcast to all ranks in a memory device; and
in response to a determination that the memory command is to be broadcast to all ranks in a memory device, insert the first predetermined value into the all ranks parameter.

3. The memory controller of claim 1, wherein the memory command comprises at least one of an activate command, a precharge command, or a refresh command.

4. The memory controller of claim 1, wherein the command is transmitted to the memory device via a memory interface.

5. An apparatus comprising:
a processor; and
a memory control logic to:
insert a first predetermined value into an all ranks parameter in a memory command; and
transmit the memory command to a memory device.

6. The apparatus of claim 5, further comprising logic to:
determine whether a memory command is to be broadcast to all ranks in a memory device; and
in response to a determination that the memory command is to be broadcast to all ranks in a memory device, insert the first predetermined value into the all ranks parameter.

7. The apparatus of claim 5, wherein the memory command comprises at least one of an activate command, a precharge command, or a refresh command.

8. The apparatus of claim 5, wherein the command is transmitted to the memory device via a memory interface.

9. A command decoder comprising logic to:
receive a memory command comprising an all ranks parameter; and
broadcast the memory command to all ranks in a memory device coupled to the command decoder when the all ranks parameter holds a first predetermined value.

10. The command decoder of claim 9, wherein the memory command further comprises a rank select parameter, and further comprising logic to:
disregard the rank select parameter when the all ranks parameter holds the first predetermined value.

11. The command decoder of claim 9, wherein the memory command further comprises a rank select parameter, and further comprising logic to:
apply the rank select parameter when the all ranks parameter holds a second predetermined value.

12. A memory device, comprising:
a plurality of memory chips organized into two or more memory ranks;
a command decoder coupled to the plurality of memory chips comprising logic to:
receive a memory command comprising an all ranks parameter; and
broadcast the memory command to all ranks in a memory device coupled to the command decoder when the all ranks parameter holds a first predetermined value.

13. The memory device of claim 12, wherein the memory command further comprises a rank select parameter, and the controller further comprises logic to:
disregard the rank select parameter when the all ranks parameter holds the first predetermined value.

14. The memory device of claim 12, wherein the memory command further comprises a rank select parameter, and the controller further comprises logic to:
apply the rank select parameter when the all ranks parameter holds a second predetermined value.

15. An electronic device, comprising:
at least one electronic component;
a memory controller comprising logic to:
insert a predetermined value into an all ranks parameter in a memory command; and
transmit the memory command to a memory device, the memory device comprising:
a plurality of memory chips organized into two or more memory ranks;
a command decoder coupled to the plurality of memory chips comprising logic to:
receive the memory command comprising the all ranks parameter; and
broadcast the memory command to all ranks in the memory device coupled to the command decoder when the all ranks parameter holds a first predetermined value.

16. The electronic device of claim 15, wherein the memory controller further comprises logic to:
determine whether a memory command is to be broadcast to all ranks in a memory device; and
in response to a determination that the memory command is to be broadcast to all ranks in a memory device, insert the first predetermined value into the all ranks parameter.

17. The electronic device of claim 15, wherein the memory command comprises at least one of an activate command, a precharge command, or a refresh command.

18. The electronic device of claim 15, wherein the memory command is transmitted to the memory device via a memory interface.

19. The electronic device of claim 15, wherein the memory command further comprises a rank select parameter, and the command decoder further comprises logic to:
disregard the rank select parameter when the all ranks parameter holds the first predetermined value.

20. The electronic device of claim 15, wherein the memory command further comprises a rank select parameter, and the command decoder further comprises logic to:
apply the rank select parameter when the all ranks parameter holds a second predetermined value.
